(19) United States
(12) Patent Application Publication
(10) Pub. No.: US 2026/0023318 A1
(43) Pub. Date: Jan. 22, 2026

(54) PELLICLE FRAME AND PELLICLE ASSEMBLY WITH THE SAME

(71) Applicant: S&S TECH CO., LTD., Daegu (KR)

(72) Inventor: Sang-Min JEONG, Daegu (KR)

(21) Appl. No.: 19/268,877

(22) Filed: Jul. 14, 2025

(30) Foreign Application Priority Data
Jul. 22, 2024 (KR) 10-2024-0096119
Apr. 15, 2025 (KR) 10-2025-0048508

(51) Int. Cl. G03F 1/64; G03F 1/22; G03F 1/44

(52) U.S. Cl. CPC G03F 1/64; G03F 1/44; G03F 1/22

(57) ABSTRACT

Pellicle frame having a pair of frame members is provided. Each of the frame member is formed to correspond to the shape of a support part of the pellicle. These frame members are mutually coupled with their plate surfaces overlapped to form a two-layer structure. Recessed portions are formed on mutually corresponding areas of the opposing inner surfaces of the frame members. These recessed portions create vent holes that open laterally from the plate surfaces when the frame members are coupled. A filter is interposed within each vent hole. This configuration facilitates easy cleaning and inspection of the pellicle frame and minimizes particle generation during the processing of the filter material. Additionally, it provides a sufficient buffering effect to protect the membrane from pressure changes within the internal space of the pellicle frame, thereby preventing damage to the membrane.

### CROSS-REFERENCE TO RELATED APPLICATIONS

This application is based on and claims priority under 35 U.S.C. § 119 to Korean Patent Applications No. 10-2024-0096119 filed on Jul. 22, 2024 and No. 10-2025-0048508 filed on Apr. 15, 2025 in the Korean Intellectual Property Office, the disclosures of which are incorporated by reference herein in their entirety.

### TECHNICAL FIELD

The present invention relates to a pellicle frame, and more particularly, to a pellicle frame used for mounting a pellicle on top of a photomask, and to a pellicle assembly that includes this pellicle frame.

### BACKGROUND ART

Extreme Ultra-Violet (EUV) lithography technology, which uses EUV exposure light with a wavelength of 13.5 nm, is being developed to implement fine patterns. In lithography processes, a photomask is used as a master plate for patterning. When particles or other contaminants adhere to the photomask, the exposure light may be absorbed or reflected by these contaminants, potentially damaging the transferred pattern. Thus, a pellicle is mounted above the photomask to prevent contaminants from adhering to the photomask surface. As circuit line widths continue to decrease, the size of contaminants affecting pattern damage has also reduced, making the role of pellicles in photomask protection increasingly important.

FIG. 1 is a diagram showing a pellicle assembly with a pellicle attached to a frame.

The pellicle assembly 80 comprises a pellicle 30 and a pellicle frame 50.

The pellicle 30 includes a rectangular membrane 20 that transmits exposure light and a support part 10 to support the membrane 20. Typically, the pellicle 30 as illustrated in FIG. 1 is manufactured by forming the membrane 20 on a silicon substrate and then etching the lower surface of the substrate to form the support part 10.

Once the pellicle 30 with the membrane 20 and the support part 10 is complete, the pellicle frame 50 is attached to the lower surface of the support part 10. For use in exposure processes, the pellicle 30 must be mounted on a photomask P, and as a preliminary step, the pellicle frame 50 is attached to the lower surface of the support part 10. An adhesive is applied to the upper surface of the pellicle frame 50 to bond the support part 10 and the pellicle frame 50. With the support part 10 of the pellicle 30 attached to the upper surface of the pellicle frame 50, the pellicle assembly 80 is completed.

When this pellicle assembly 80 is adhered to the photomask P, the pellicle 30 becomes mounted on the photomask. To adhere the pellicle assembly 80 to the photomask P, an adhesive is applied to the lower surface of the pellicle frame 50.

The pellicle assembly 80, mounted on the photomask P, is then used within an exposure device. During the exposure process, the interior of the exposure device is maintained in a vacuum state, and air within the device is vented to the outside before exposure processing. Due to this venting pressure, air within the internal space S of the pellicle assembly 80, more precisely within the space formed by the pellicle 30, pellicle frame 50, and photomask P, is evacuated, causing pressure on the pellicle 30. This can result in damage to the very thin membrane 20. To prevent this, the pellicle frame 50 is formed with vent holes.

FIG. 2 is an enlarged cross-sectional view of FIG. 1, showing the detailed structure of the pellicle frame 50. The pellicle frame 50 has a columnar cross-section and a rectangular frame shape open vertically on a plane.

The pellicle frame 50 includes vent holes 52 formed to penetrate the sidewall, spaced horizontally along the sidewall at intervals. As the pellicle assembly 80 is mounted on the photomask P, the vent holes 52 functions to allow communication between the internal space S, formed between the pellicle assembly 80 and the photomask P, and the external space. During the vacuuming process of the device, air from the internal space S is vented outside through the vent holes 52, preventing a pressure difference between the internal space S and the exterior of the pellicle assembly 80, thereby avoiding damage to the membrane 20.

While the vent holes 52 function to prevent membrane 20 damage, they may also pose a risk by allowing particles from the external environment to enter the internal space S. To prevent the infiltration of external particles, filters 56 are installed in the vent holes 52. The filters 56 are arranged as filtering membranes positioned vertically across the vent holes 52. To install the filters 56, filter receiving openings 52a are formed in the central part of each vent hole 52, penetrating the pellicle frame 50 vertically, to accommodate the upper and lower regions of each filter 56. The filters 56 are then installed by being inserted through the receiving openings 52a in the pellicle frame 50.

Air entering the internal space S through the vent holes 52 is filtered by the filters 56, thereby preventing the infiltration of external contaminants or particles into the internal space S.

In conventional structures, however, a machining process is required to form vent holes 52 on the side of the pellicle frame 50 for filter 56 installation. For example, a precise drilling process is necessary to create the vent holes 52. Such processes generate particles, making it essential to perform precise cleaning to remove particles from the vent holes 52 after formation. However, since the vent holes 52 have a very small diameter and penetrate the relatively thick sidewall of the pellicle frame 50, cleaning and inspecting for residual particles inside the vent holes 52 is challenging.

Moreover, in this conventional structure, since the filters 56 need to traverse the vent holes 52 for coverage after installation, they must be processed into a form resembling a broad rectangular membrane with a specific thickness. Thus, to fabricate the filters 56, a filter material in the shape of a rectangular column must be prepared and then sliced thinly. This process results in the entire outer surface of the filter 56 being formed from cut surfaces created by the cutting tool. Consequently, the filter's 56 outer surface becomes covered in particles generated during cutting, meaning the filter 56, intended to prevent particles, may itself become a source of particles.

Additionally, in the conventional pellicle frames, strengthening the filtering capability of the filter 56 can inadequately protect the membrane 20 against pressure changes in the internal space S. For instance, improving the filtering performance of the filter 56 requires a higher filter density, thereby increasing the sealing strength of the vent hole 52. As a result, if there is a significant pressure change within the internal space S, the strong blocking force of the filter 56 may prevent the vent hole 52 from buffering the pressure change, potentially damaging the membrane 20. Conversely, reducing the filter 56 density to increase the buffering effect of the vent hole 52 during high-pressure changes weakens the filtering performance of the filter 56.

### SUMMARY OF THE INVENTION

The present invention has been devised to address the above issues, and the object of the invention is to provide a pellicle frame that facilitates easy cleaning and inspection.

Another object of the present invention is to provide a pellicle frame that can minimize particle generation during the filter manufacturing process.

Still another object of the present invention is to provide a pellicle frame that can achieve both sufficient buffering for membrane protection against pressure changes in the internal space of the pellicle frame while enhancing filtering efficiency.

To achieve the above objects, the present invention provides a pellicle frame used for mounting a pellicle on a photomask by attaching the pellicle thereon, the pellicle including a membrane for transmitting exposure light and a support part for supporting the outermost edge region of the membrane, the pellicle frame comprising: a pair of frame members each formed to match a shape of the support part, with plate surfaces thereof mutually coupled and overlapped to create a two-layer structure, and each formed with recessed portions on mutually corresponding areas of opposing inner surfaces, the recessed portions forming a vent hole opened laterally from the plate surfaces in coupled state; and a filter disposed between the pair of frame members in the vent hole to block the vent hole.

A plurality of said recessed portions are formed on each of the frame member to form a plurality of said vent holes.

It is preferable that a height of the filter in cross-section is greater than a height of the vent hole.

A receiving groove is formed on a bottom surface of each of the recessed portion to accommodate a part where the filter contacts the bottom surface.

The receiving groove is formed along a longitudinal direction of the bottom surface.

A cross-section of the receiving groove has a partial circular arc shape, and the filter is formed to have a cross-section of a circular shape.

As another fashion, a cross-section of the receiving groove has a partial polygonal shape, and the filter is formed to have a cross-section of a polygonal shape.

The filter preferably has a tubular shape.

A length of the receiving groove along the longitudinal direction is greater than a length of the recessed portion.

Sections at both ends of the receiving groove that extend beyond the recessed portion are formed to have a cross-section of a semi-circular shape or a polygonal shape.

An adhesive can be applied to at least a part of the receiving groove to provide adhesion to the filter.

At least one of the pair of frame members has a pinhole on a side thereof, the pinhole being formed to provide an area for pin insertion from an outside to hold the pellicle frame.

Each of the frame members has an engagement part formed to be combined with each other by mutual fitting.

The engagement part is formed between a plurality of said vent holes.

According to another embodiment of the present invention, the filter is placed within the vent hole as a filter fixing device is installed between the pair of frame members with the filter fixed in the filter fixing device, and the filter fixing member has a ventilation part that partially exposes the filter so that the vent hole is blocked by the filter.

Preferably, in such an embodiment, the filter has a shape of a sheet that extends horizontally and is arranged with its surface standing upright, the filter fixing device includes a pair of fixing members to which both sides of the filter contact respectively, and each of the fixing members has the ventilation part formed in an inner area of its edge area.

According to one modification thereof, at least one of the fixing members has a receiving part for receiving the filter, the receiving part being formed to be recessed on the edge area of a surface that contacts the filter.

According to another modification thereof, a recess is formed in one of the fixing members and a protrusion is formed in the other fixing member, so that the pair of fixing members are mutually engaged by inserting the protrusion into the recess.

The protrusion is inserted into the recess with a part of the filter inserted into the recess.

According to another aspect of the present invention, a pellicle assembly is provided, which comprises a pellicle frame with the construction as described above, and a pellicle attached to the pellicle frame.

According to the present invention, the pellicle frame is formed by coupling two frame members arranged vertically and creating vent holes between the combined members, so easy cleaning and inspection of particles can be achieved.

Moreover, filters are manufactured by cutting tubular filter materials to a specified length in the longitudinal direction, so the cut surface area is minimized to reduce particle generation during the cutting process. Furthermore, the cut surface is not placed within the vent hole, thus preventing particles from entering the internal space of the pellicle assembly.

Moreover, in the present invention, the filter is manufactured in a tubular shape and positioned along the longitudinal direction of the plate surface of the pellicle frame, allowing a single filter to provide double-layered shielding for the vent hole. Thus, even with a lower filter density, sufficient filtering can be achieved through double filtering. Additionally, if there is a sudden pressure change between the interior and exterior of the pellicle frame, the space between the double-layered filters buffers the pressure change, thereby preventing damage to the membrane.

Furthermore, by adopting the method of fixing the filter within the filter fixing device and installing the filter fixing device within the vent hole, the assembly process of the filter can be performed more easily.

### BRIEF DESCRIPTION OF THE DRAWINGS

FIG. 1 illustrates a pellicle assembly with a pellicle attached to a frame,

FIG. 2 is a partial enlarged sectional view of FIG. 1,

FIG. 3 is an exploded perspective view of the pellicle frame according to the present invention,

FIG. 4 is a side view of the pellicle frame in an assembled state from FIG. 3,

FIG. 5 is a top view of the first frame member in FIG. 3,

FIG. 6 is a partial perspective view of FIG. 5,

FIG. 7 is a bottom view of the second frame member in FIG. 3,

FIG. 8 is a partial perspective view of FIG. 7,

FIG. 9 is a partial enlarged view of part of FIG. 6,

FIG. 10 illustrates the state that the filter is installed in FIG. 9,

FIG. 11 is an enlarged perspective view of the filter in FIG. 10,

FIG. 12 shows the filter material for manufacturing the filter in FIG. 10, and

FIG. 13 is a sectional view of the vent hole portion of FIG. 4.

FIG. 14 is an exploded perspective view of a filter assembly used in a pellicle frame according to the second embodiment of the present invention.

FIG. 15 is a perspective view showing the assembled state of FIG. 14.

FIG. 16 is a view similar to FIG. 10 showing the state where the filter assembly of FIG. 15 is mounted.

FIG. 17 is a view similar to FIG. 13 showing a cross-section of the state where the filter assembly of FIG. 15 is mounted.

FIG. 18 is an exploded perspective view of a filter assembly according to the first modification of the second embodiment of the present invention.

FIGS. 19 and 20 are enlarged views of parts A and B of FIG. 18, respectively.

FIG. 21 is a view similar to FIG. 17, showing a cross-section of the state where the filter assembly of FIG. 18 is mounted.

FIG. 22 is an exploded perspective view of a filter assembly according to the second modification of the second embodiment of the present invention.

FIGS. 23 and 24 are enlarged views of parts C and D of FIG. 22, respectively.

FIG. 25 is a side view showing the state where the filter is attached to the first fixing member in FIG. 22.

FIG. 26 is a partially enlarged cross-sectional view of the state where the first fixing member and the second fixing member are engaged with each other in FIG. 22.

FIGS. 27 to 30 are views showing a filter assembly according to the third modification of the second embodiment of the present invention in a manner similar to FIGS. 22 to 25, respectively.

### DETAILED DESCRIPTION OF THE INVENTION

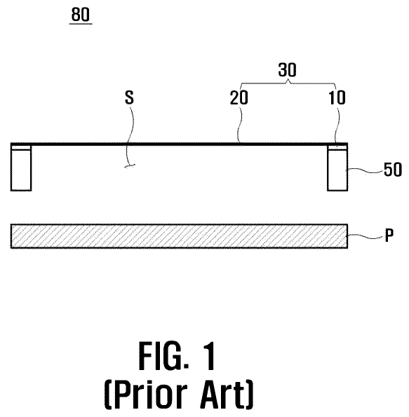

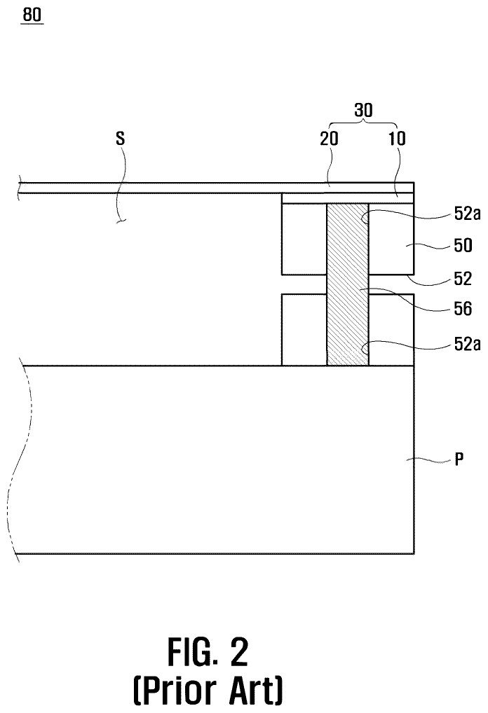

The invention will be described in detail with reference to the accompanying drawings. The general structure of a pellicle assembly is omitted for brevity, as it has been described with reference to FIGS. 1 and 2. Identical reference numerals are used to denote elements shown in FIGS. 1 and 2 related to the pellicle in this description.

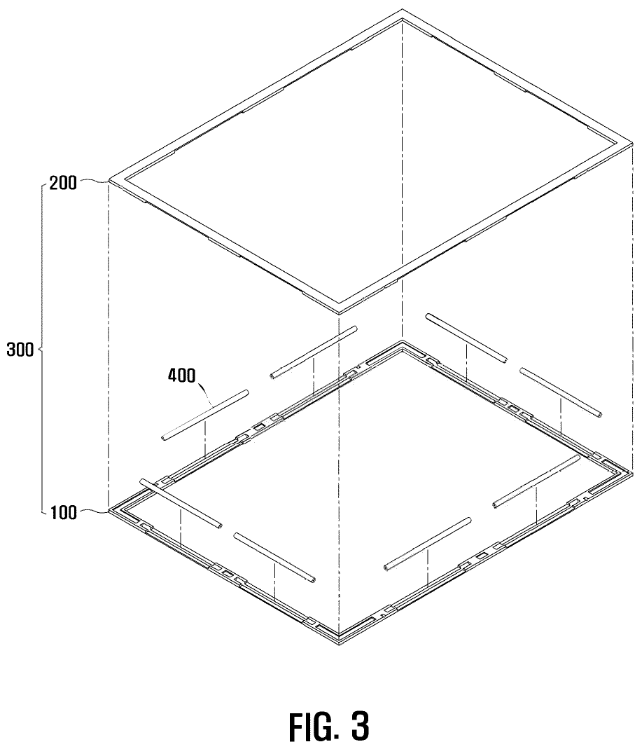

Hereinbelow, the first embodiment of the present will be described with reference to FIGS. 3 to 13.

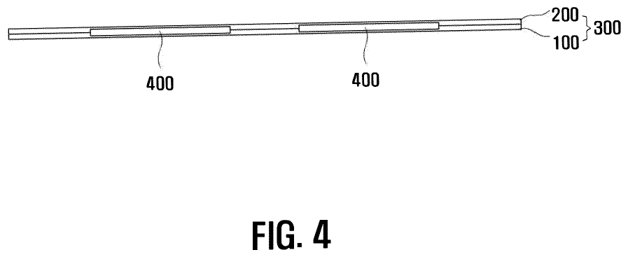

FIG. 3 is an exploded perspective view of the pellicle frame according to the first embodiment of the present invention, and FIG. 4 is a side view of the assembled state of FIG. 3. As in the case of the conventional art illustrated above, the pellicle frame 300 is mounted on top of the photomask P after the pellicle 30 is attached. The pellicle 30 includes a rectangular membrane 20 for transmitting exposure light and a support part 10 that supports the outer edge region of the membrane 20.

The pellicle frame 300 of the present invention includes a pair of frame members 100 and 200, specifically a first frame member 100 and a second frame member 200, as well as a filter 400.

Each of the first and second frame members 100, 200 is formed in a rectangular frame shape corresponding to the support part 10 of the pellicle 30. This rectangular frame shape refers to an overall rectangular plate form, with only the edge regions remaining and the rest removed. The removed area corresponds to the window region through which EUV exposure light passes, except for the area of the membrane 20 where the support part 10 is formed. Consequently, each frame member 100, 200 has a structure that four elongated bars form a rectangular frame. Each frame member 100, 200 is manufactured as a single body through a single molding process.

The first and second frame members 100 and 200 are mutually coupled to form a two-layer structure by overlapping their plate surfaces. Specifically, the first frame member 100 is positioned at the bottom and the second frame member 200 is positioned at the top, coupling vertically. The filter 400 is disposed between the two frame members 100 and 200.

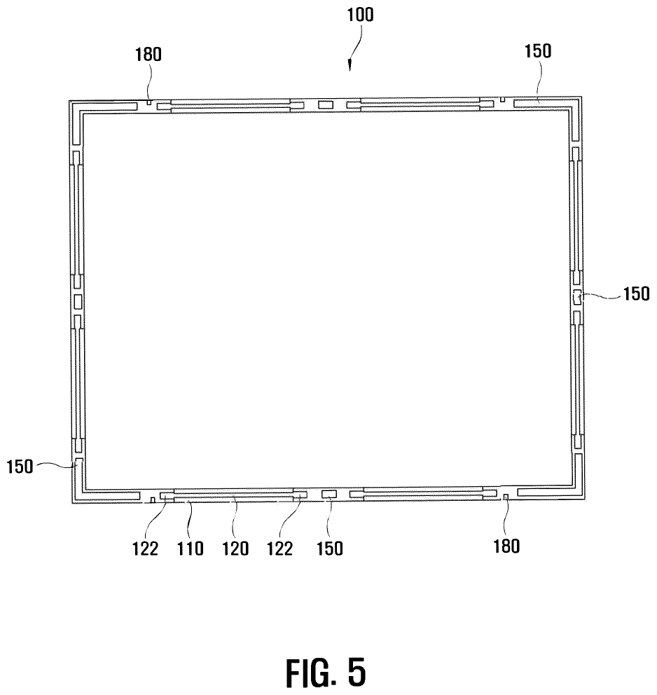

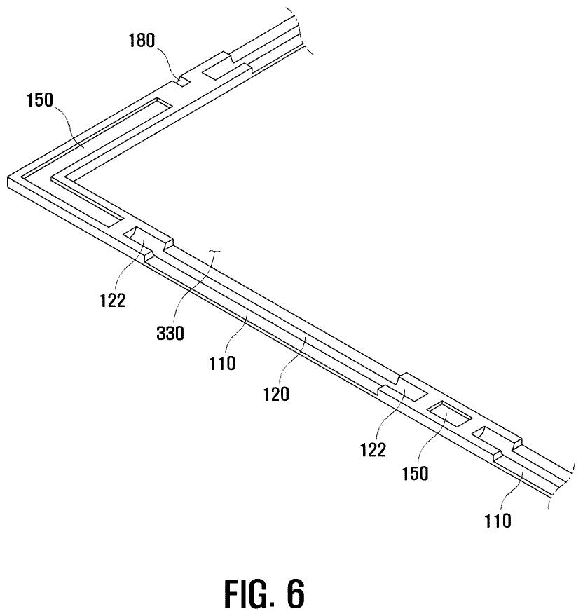

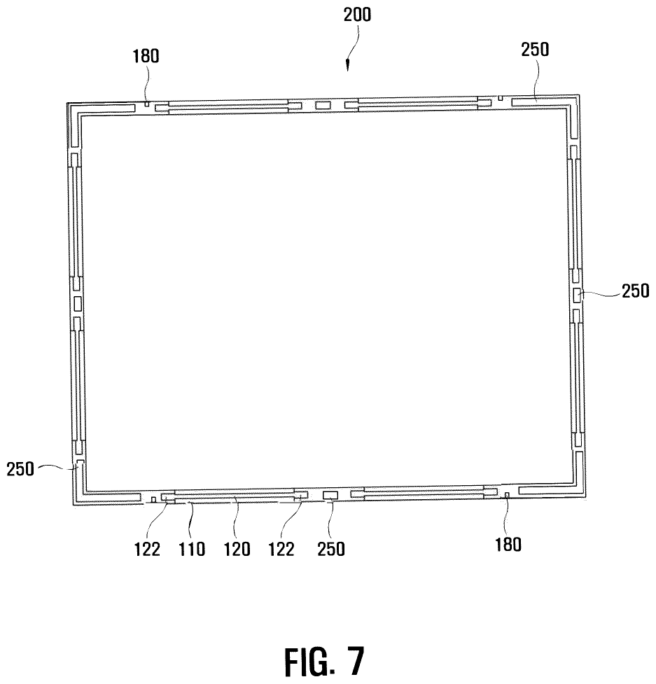

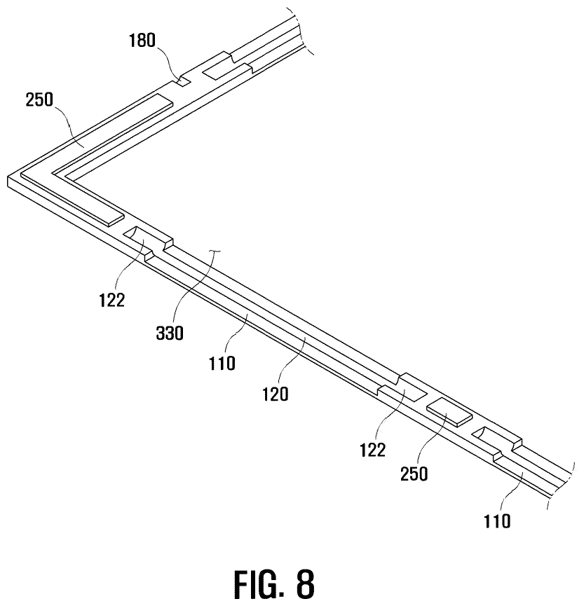

FIGS. 5 and 6 show the first frame member 100 in FIG. 3, while FIGS. 7 and 8 show the second frame member 200. FIGS. 7 and 8 depict the inverted state from the state of FIG. 3, for the clarity of the construction of the second frame member 200.

Each frame member 100, 200 has recessed portions 110 on its inner surfaces (i.e., the upper surface of the first frame member 100 and the lower surface of the second frame member 200) formed in mutually corresponding areas. When the two frame members 100 and 200 are coupled, opposing recessed portions 110 form a vent hole 330 that opens laterally from the plate surface of the pellicle frame 300. The filter 400 is interposed within this vent hole 330 to block it. A plurality of recessed portions 110 on each frame member 100, 200 form a plurality of vent holes 330.

Each recessed portion 110 is formed in a certain area along a longitudinal direction of the respective frame members 100, 200 in a shape that is recessed to a uniform depth from the plate surface. Additionally, each recessed portion 110 spans the entire width of the plate surface of the frame members 100, 200.

The bottom surface of each recessed portion 110 includes a receiving groove 120 recessed further from the recessed portion 110. This receiving groove 120 is formed along the longitudinal direction of the bottom surface of the recessed portion 110, with both ends 122 extending outward beyond the recessed portion 110.

The receiving groove 120 is shaped to correspond to the outer shape of the filter 400, specifically with a partially circular arc cross-section. However, the shape is not limited to that shape, and it may vary depending on the shape of the filter 400. The filter 400 can have the shape of a polygonal cross-section, such as a rectangular cross-section.

The filter 400 is positioned along the length of the recessed portion 110, with its cross-section shaped as a circular form, or specifically a tubular form. However, the filter 400 is not necessarily limited to a tubular shape and may have a polygonal form or circular form with a plurality of pores. Part of the filter 400 that contacts the bottom surface of the recessed portion 110 is accommodated within the receiving groove 120. The receiving groove 120 stably maintains the fixed position of the filter 400 within the vent hole 330. To further enhance the fixation strength of the filter 400, an adhesive may be applied within the receiving groove 120 to provide adhesion to the filter 400. The adhesive can be applied to the entire length of the receiving groove 120 or only to specific sections. For example, the adhesive may be applied only to the ends 122 of the receiving groove 120, which are outside the recessed portion 110.

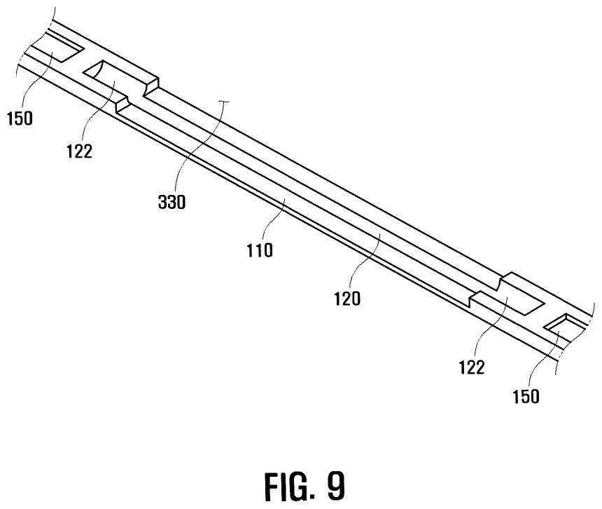

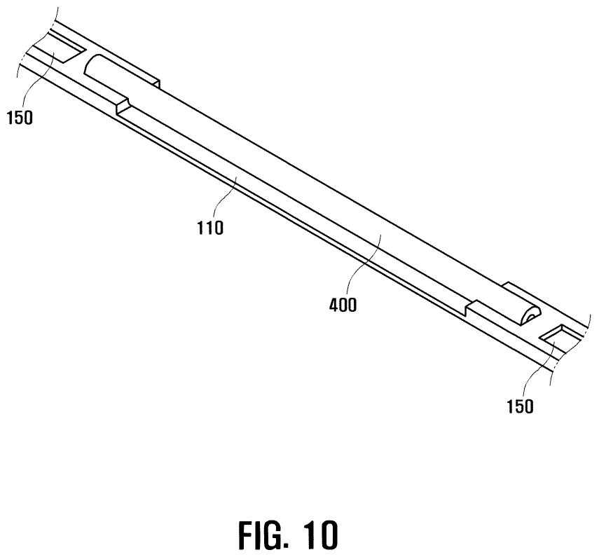

FIG. 9 is a partial enlarged view of FIG. 6, and FIG. 10 shows the state in which the filter 400 is installed in FIG. 9.

As described above, the receiving groove 120 is longer in its longitudinal direction than the length of the recessed portion 110 itself. Specifically, the receiving groove 120 is recessed from the bottom surface of the recessed portion 110, with its ends 122 extending beyond the section of the recessed portion 110 and directly recessed from the plate surface of each frame member 100, 200. The extended ends 122 of the receiving groove 120, beyond the recessed portion 110, are semi-circularly shaped to fit the tubular filter 400.

With this structure, as shown in FIG. 10, almost all of the part of the filter 400 is positioned within the recessed portion 110, with remaining part at each end of the filter 400 extending into the semi-circular ends 122 of the receiving groove 120. The filter 400 is configured to have a height in its cross-section greater than the height of the vent hole 330. As a result, portions of the top and bottom of the filter 400 are respectively accommodated within the upper and lower receiving grooves 120, thus securing the position of the filter 400 within the recessed portion 110. When the two frame members 100 and 200 are coupled, the filter 400 remains interposed within the vent hole 330, shielding it, while the ends of the filter 400 are pressed and secured by the coupling of the ends 122 of the two receiving grooves 120.

If the filter 400 has a polygonal cross-section, the ends 122 of the receiving groove 120 are shaped to correspond to the polygonal shape, thus accommodating half of the filter's cross-section.

Each frame member 100, 200 includes an engagement part 150, 250 formed to combine by mutual fitting. Specifically, the second frame member 200, as shown in FIGS. 7 and 8, includes a protrusion 250 that protrudes from its inner surface, while the inner surface of the first frame member 100 includes a recess 150 corresponding to this protrusion 250, forming an engagement part 150, 250. This engagement part 150, 250 couples the first and second frame members 100 and 200.

In the embodiment of the present invention, eight engagement parts 150, 250 are formed at the four corners and four edges of the pellicle frame 300. The number of engagement parts 150, 250 can be adjusted as needed. Engagement parts 150, 250 at the corners are generally “L”-shaped to match the bent surface of the corners. The engagement parts 150, 250 can be variously configured as long as they enable detachable coupling by mutual fitting. Engagement parts 150, 250 are positioned between the vent holes 330, thus alternating with the vent holes 330 along the plate surface of the pellicle frame 300.

The side of the frame members 100, 200 includes a pinhole 180, which provides a gripping area for external equipment to hold the pellicle frame 300 using pins. The external equipment may grip the pellicle frame 300 for purposes such as moving it to a storage location or mounting it onto the photomask P. The pinhole 180 is formed at least at two locations, such as two opposite locations, on the pellicle frame 300, allowing external equipment to insert pins at multiple points to hook the pellicle frame 300.

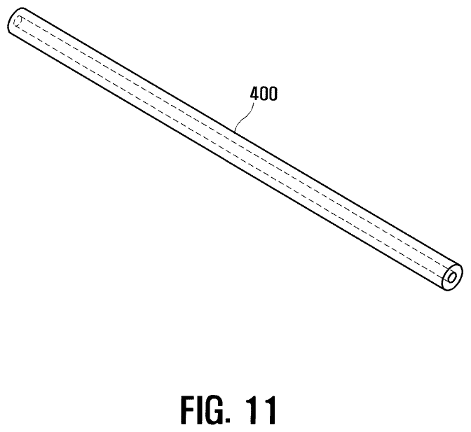

FIG. 11 is an enlarged perspective view of the filter 400 shown in FIG. 10. The filter 400 of the present invention has an overall tubular shape. The material of the filter 400 may be appropriately selected as needed, preferably one with multiple pores.

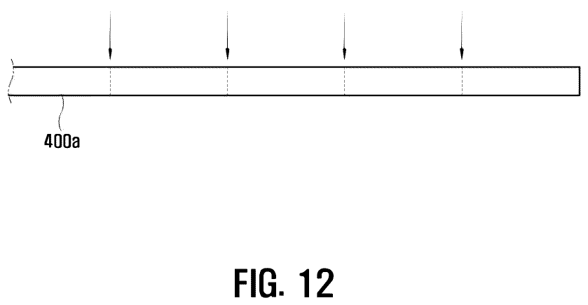

FIG. 12 shows the filter material for manufacturing the filter in FIG. 10. A very long tubular filter material 400a is prepared, and each filter 400 can be obtained by cutting the filter material 400a to a predetermined length in the direction of the arrow, as shown in FIG. 11. By cutting the tubular filter material 400a, the cut surfaces become the ends of each filter 400. When the filter 400 is installed as shown in FIG. 10, the cut surfaces are positioned in both ends 122 of the receiving grooves 120, and thus are not exposed to external air within the vent hole 330 in the state that the first frame member 100 and the second frame member 200 are coupled as shown in FIG. 4. Consequently, contamination on the cut surfaces from the filter manufacturing process does not function as particles.

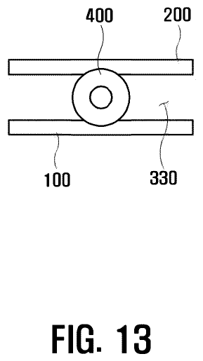

FIG. 13 is a sectional view of the vent hole portion of FIG. 4.

When the filter 400 is positioned between the two frame members 100, 200, the tubular cross-sectional structure of the filter 400 forms a double-layer structure in the direction of air inflow/outflow through the vent hole 330. This double-filtering effect allows sufficient filtering even if the density of the filter 400, i.e., the sealing strength of the vent hole 300, is reduced. Furthermore, even if a sudden pressure change occurs between the interior and exterior of the pellicle frame 300, the space within the tube, that is, the space in the double-layered filter, provides a buffering effect, effectively preventing membrane 20 damage.

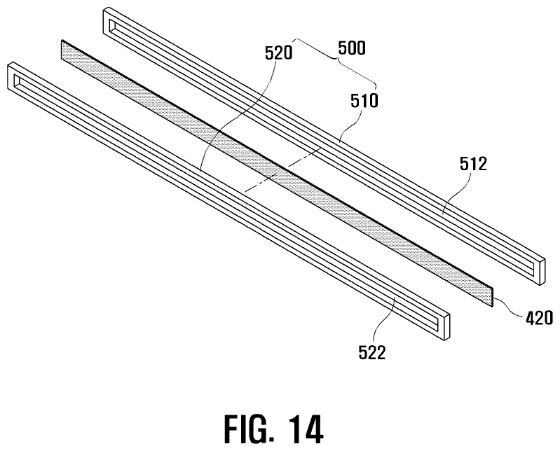

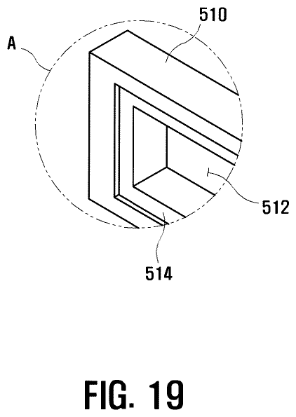

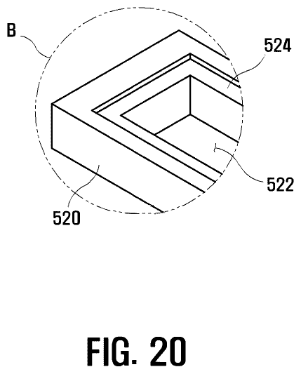

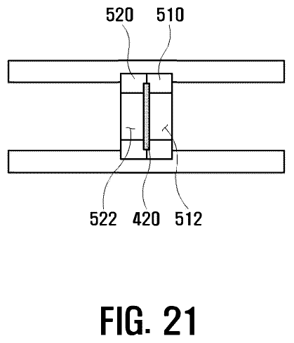

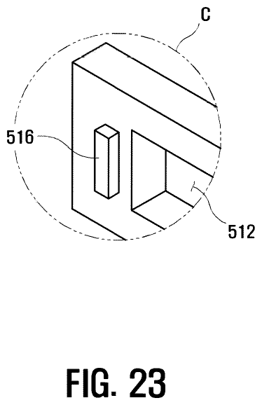

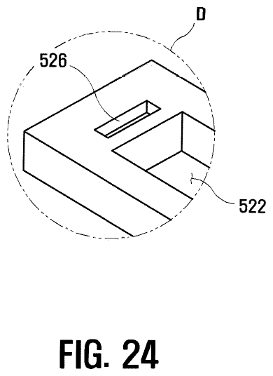

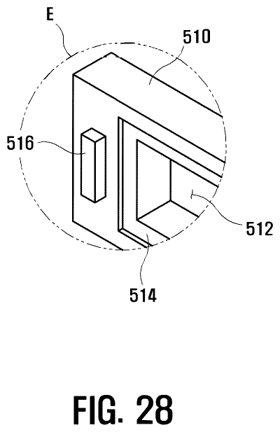

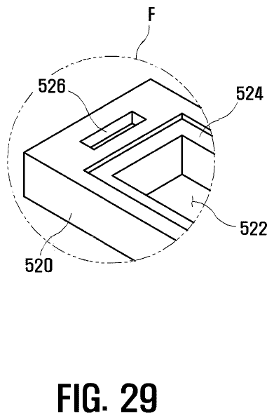

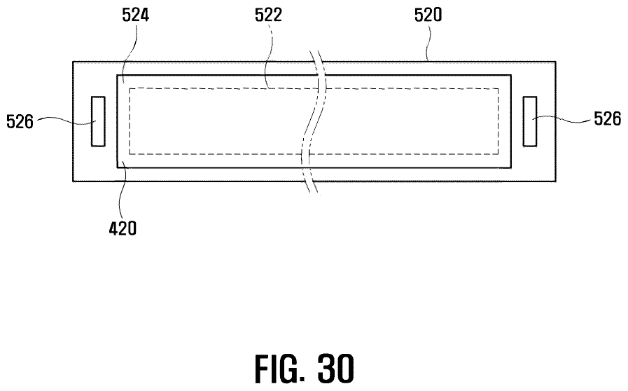

Hereinafter, the second embodiment of the present invention will be described with reference to FIGS. 14 to 30.

In the following description of the second embodiment, detailed explanations will be omitted for configurations that are substantially the same with those described in the first embodiment, and such configurations are incorporated as the configurations of the second embodiment. For the convenience of illustration and description, the same reference numerals are used to cite substantially same configurations.

FIGS. 14 to 17 illustrate the basic configuration of the second embodiment of the present invention.

The second embodiment differs from the aforementioned first embodiment in that a filter assembly comprising a filter 420 and a filter fixing device 500 is employed instead of the filter 400. That is, the filter 420 is not installed alone within the vent hole 330, but is installed within the vent hole 330 after being prepared as a filter assembly fixed within the filter fixing device 500. The following description details the configuration of the filter assembly.

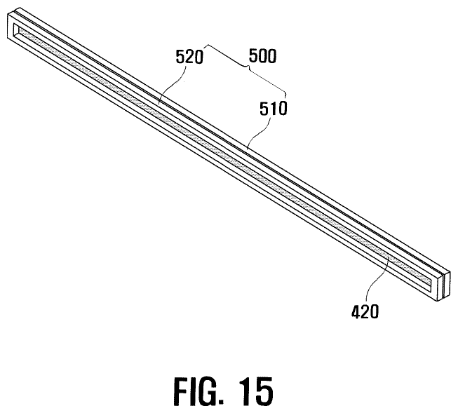

FIG. 14 is an exploded perspective view of the filter assembly used in the pellicle frame, and FIG. 15 is a perspective view showing the assembled state of FIG. 14.

In this embodiment, the filter 420 has an overall rectangular sheet shape, which extends horizontally and is arranged with its surface standing upright. The filter fixing device 500 functions to secure this filter 420. Specifically, the filter 420 is fixed to the filter fixing device 500, and in this state, the filter fixing device 500 is installed between a pair of frame members 100 and 200, thereby placing it within the vent hole 330.

The filter fixing device 500 includes a pair of fixing members 510 and 520 that each contact to the filter 420 on both sides of the filter 420. Each fixing member 510, 520 has an overall rectangular frame shape. Specifically, the first fixing member 510 has a shape where the inner area thereof is removed from a horizontally elongated rectangular plate shape, leaving only the edge area, thereby forming a ventilation part 512. Similarly, the second fixing member 520 also has a shape where only the edge area of an elongated rectangle remains, and a ventilation part 522 is formed in its inner area. The first fixing member 510 and the second fixing member 520 have substantially identical shapes. As the first fixing member 510 and the second fixing member 520 are connected with the filter 420 between them, the outer surfaces of the edge area of the filter 420 contact the inner surfaces of the edge areas of the first fixing member 510 and the second fixing member 520 respectively, and the remaining area of the filter 420 is exposed to the outside through the ventilation parts 512 and 522. The overall size of the filter 420 is made somewhat smaller than the size of the first fixing member 510 and the second fixing member 520, and accordingly, in the state shown in FIG. 15, the filter 420 is not exposed laterally from its surface between the two fixing members 510 and 520.

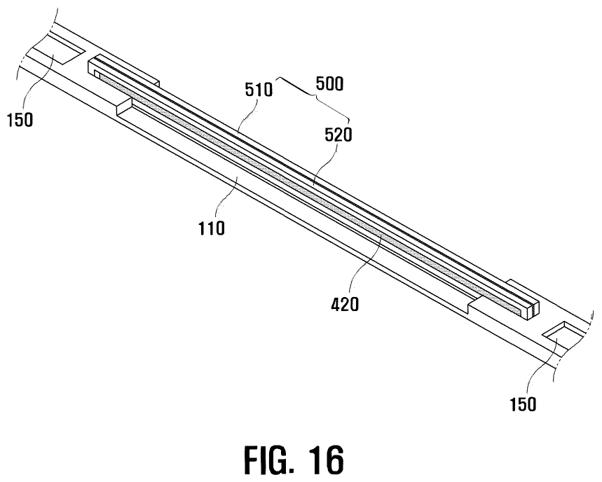

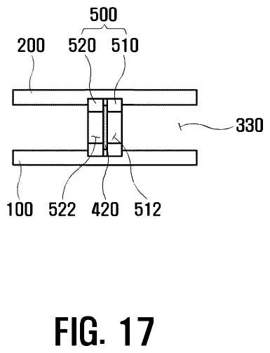

FIG. 16 is a view similar to FIG. 10 showing the filter assembly of FIG. 15 mounted between the frame members 100 and 200, and FIG. 17 is a view similar to FIG. 13 showing a cross-section of the mounted state of the filter assembly of FIG. 15.

In the first embodiment shown in FIGS. 10 and 13, the filter 400 is mounted between frame members 100 and 200 of the pellicle, but in the second embodiment, the filter assembly in the state shown in FIG. 15, comprising the filter 420 and the filter fixing device 500, is mounted between the frame members 100 and 200. In the first embodiment, since the filter 400 has a tubular shape, the receiving groove 120 formed on the frame members 100 and 200 and the cross-sectional shape of its both ends 122 have a partial arc shape to partially accommodate the tubular-shaped filter 400. However, in this embodiment, since the filter assembly has an overall rectangular cross-sectional shape, the cross-sectional shape of the receiving groove 120 and its both ends 122 also have a shape that can partially accommodate this rectangular cross-sectional filter assembly. As shown in FIG. 17, due to the ventilation parts 512 and 522, the remaining area of the filter 420 except for its edge area is placed in an upright direction within the vent hole 330. Consequently, the surface of the sheet-shaped filter 420 blocks the vent hole 330, so that air passing through the vent hole 330 is filtered by the filter 420.

According to this second embodiment, a filter assembly combining the filter 420 and the filter fixing device 500 is manufactured separately, and the pellicle frame production is completed by placing this filter assembly at the position of the vent hole 330 between the first frame member 100 and the second frame member 200 and then mutually combining the two frame members 100 and 200. Unlike the first embodiment, since the flexible filter 400 is not used in the assembly process, but rather a filter assembly with rigidity, being wrapped by the filter fixing device 500, is used in the assembly process, the workability in the assembly process is greatly improved.

Hereinafter, various modifications of this second embodiment will be described. In the following modifications, explanations for configurations identical to the basic configuration of the second embodiment described above will be omitted, and the same reference numerals are used for citation.

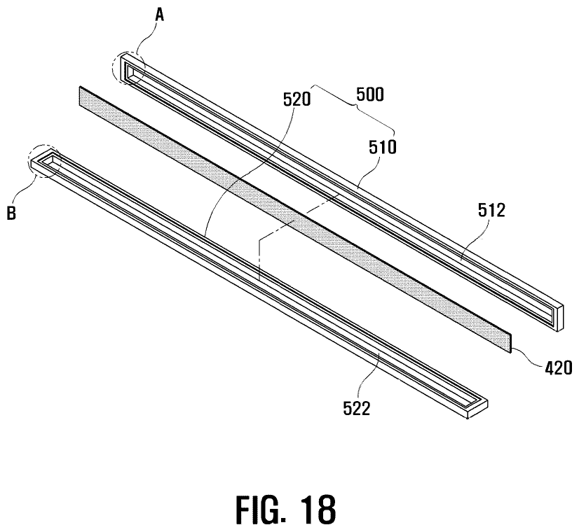

FIGS. 18 to 21 illustrate a first modification of the second embodiment of the present invention.

Compared to the basic configuration of the second embodiment, the first modification differs in that receiving parts 514 and 524 are formed on the inner surfaces of the fixing members 510 and 520, that is, the surfaces that contact the filter 420. The receiving parts 514 and 524 are formed to be recessed in the edge area of the surface that contacts the filter 420, and are formed to match the size and shape of the filter 420. Accordingly, the edge area of the filter 420 is accommodated within the receiving parts 514 and 524. By means of these receiving parts 514 and 524, the filter 420 is installed to be wrapped between the two fixing members 510 and 520. The receiving parts 514 and 524 may be formed on only one of the two fixing members 510 and 520.

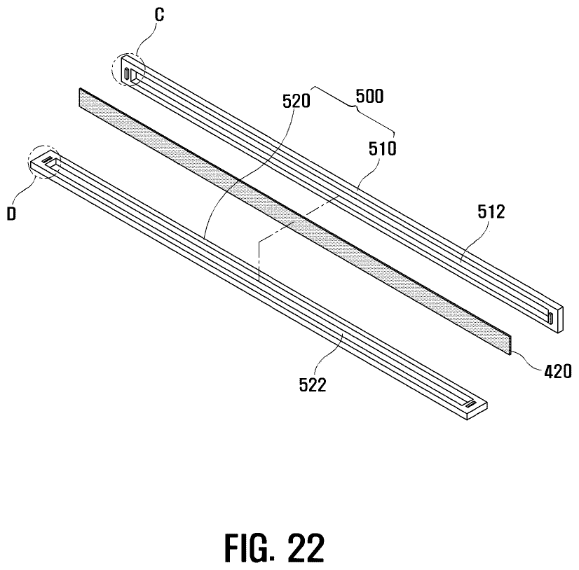

FIGS. 22 to 26 illustrate a second modification of the second embodiment of the present invention.

Compared to the basic configuration of the second embodiment, the second modification differs in that protrusions 516 and a recesses 526 are formed respectively on the inner surfaces of the fixing members 510 and 520, that is, the surfaces that contact the filter 420. The protrusions 516 are formed at positions adjacent to both ends in the longitudinal direction of the first fixing member 510, and the recesses 526 are formed at positions adjacent to both ends in the longitudinal direction of the second fixing member 520. The protrusions 516 and the recesses 526 are connected to each other by insertion, thereby mutually connecting the first fixing member 510 and the second fixing member 520.

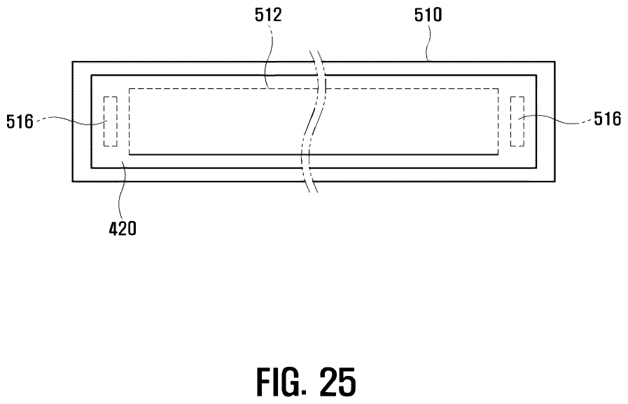

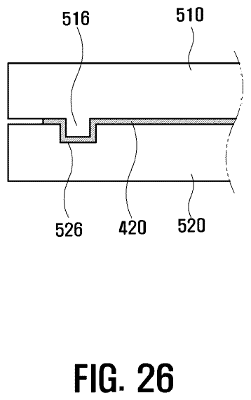

As shown in FIG. 25, the filter 420 has a length that covers the protrusions 516 on both sides of the first fixing member 510. Accordingly, when the protrusions 516 are inserted into the recesses 526, a part of the filter 420 at both sides thereof is inserted into the recesses 526 as shown in FIG. 26, fixing the position of the filter 420.

Meanwhile, in FIG. 25, the length of the protrusion 516 in the up-down direction is shown to be smaller than the width of the filter 420 in the up-down direction. However, the length of the protrusion 516 in the up-down direction may be configured to be equal to or greater than the width of the filter 420 in the up-down direction. In this case, since the length of the recess 526 in the up-down direction is also equal to or greater than the width of the filter 420 in the up-down direction, the entire area in the up-down direction at the left and right ends of the filter 420 can be inserted into the recesses 526. Accordingly, the insertion connection work of the protrusions 516 and the recesses 526 can be easily performed, and also the filter 420 can be accurately fixed at a predetermined position.

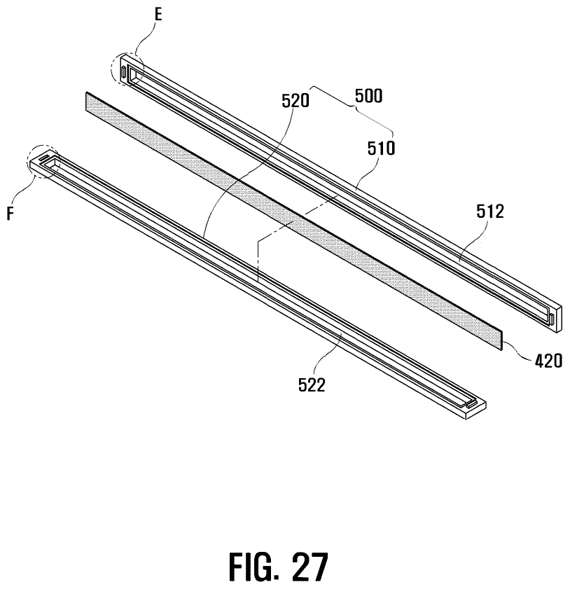

FIGS. 27 to 30 illustrate a third modification of the second embodiment of the present invention in a manner similar to FIGS. 22 to 25, respectively.

Compared to the second modification, the third modification differs in that receiving parts 514 and 524 are formed on the inner surfaces of the fixing members 510 and 520, that is, the surfaces that contact the filter 420. This third modification corresponds to a combined configuration of the aforementioned first and second modifications. The configuration and function of the receiving parts 514 and 524 are identical to those described for the first modification. In cases where receiving parts 514 and 524 are formed as in the third modification, the length of the filter 420 is configured to be shorter than in the case of the second modification so that the entire edge of the filter 420 is accommodated within the receiving parts 514 and 524. In the third modification as well, only one of the two receiving parts 514 and 524 may be formed.

Meanwhile, in the aforementioned second embodiment and its modifications, adhesive may be applied between the filter 420 and the fixing members 510 and 520 so that the filter 420 is fixed to the fixing members 510 and 520 by the adhesive force of the adhesive. The adhesive may be applied between the filter 420 and only one of the fixing members 510 and 520.

In the basic configuration of the second embodiment, it is preferable to use adhesive. Furthermore, in this basic configuration, it is preferable that adhesive is used between the filter 420 and the first fixing member 510, and between the filter 420 and the second fixing member 520. However, in the first and third modifications, since the filter 420 is accommodated within the receiving parts 514 and 524, and in the second modification, since the filter 420 is position-fixed by the insertion of the protrusions 516 into the recesses 526, adhesive may not be necessary in these modifications. In the first and third modifications, if adhesive is used, it may be applied to the recessed bottom surface of the receiving parts 514 and 524. In the second modification, if adhesive is used, it may be applied within the recesses 526.

Although the present invention has been described with reference to the accompanying drawings, the presented structures are used solely for illustration and explanation purposes and are not intended to limit the meaning or scope of the invention as defined in the claims. Accordingly, those skilled in the art will understand that various modifications and equivalent alternative structures are possible, and the true scope of the invention should be defined by the claims.

I claim:

1. A pellicle frame used for mounting a pellicle on a photomask by attaching the pellicle thereon, the pellicle including a membrane for transmitting exposure light and a support part for supporting the outermost edge region of the membrane, the pellicle frame comprising:
a pair of frame members each formed to match a shape of the support part, with plate surfaces thereof mutually coupled and overlapped to create a two-layer structure, and each formed with recessed portions on mutually corresponding areas of opposing inner surfaces, the recessed portions forming a vent hole opened laterally from the plate surfaces in coupled state; and
a filter disposed between the pair of frame members in the vent hole to block the vent hole.

2. The pellicle frame according to claim 1, wherein a plurality of said recessed portions are formed on each of the frame member to form a plurality of said vent holes.

3. The pellicle frame according to claim 1, wherein a height of the filter in cross-section is greater than a height of the vent hole.

4. The pellicle frame according to claim 1, wherein a receiving groove is formed on a bottom surface of each of the recessed portion to accommodate a part where the filter contacts the bottom surface.

5. The pellicle frame according to claim 4, wherein the receiving groove is formed along a longitudinal direction of the bottom surface.

6. The pellicle frame according to claim 5, wherein a cross-section of the receiving groove has a partial circular arc shape, and the filter is formed to have a cross-section of a circular shape.

7. The pellicle frame according to claim 5, wherein a cross-section of the receiving groove has a partial polygonal shape, and the filter is formed to have a cross-section of a polygonal shape.

8. The pellicle frame according to claim 5, wherein the filter has a tubular shape.

9. The pellicle frame according to claim 5, wherein a length of the receiving groove along the longitudinal direction is greater than a length of the recessed portion.

10. The pellicle frame according to claim 9, wherein sections at both ends of the receiving groove that extend beyond the recessed portion are formed to have a cross-section of a semi-circular shape or a polygonal shape.

11. The pellicle frame according to claim 4, wherein an adhesive is applied to at least a part of the receiving groove to provide adhesion to the filter.

12. The pellicle frame according to claim 1, wherein at least one of the pair of frame members has a pinhole on a side thereof, the pinhole being formed to provide an area for pin insertion from an outside to hold the pellicle frame.

13. The pellicle frame according to claim 1, wherein each of the frame members has an engagement part formed to be combined with each other by mutual fitting.

14. The pellicle frame according to claim 13, wherein the engagement part is formed between a plurality of said vent holes.

15. The pellicle frame according to claim 1, wherein
the filter is placed within the vent hole as a filter fixing device is installed between the pair of frame members with the filter fixed in the filter fixing device, and
the filter fixing member has a ventilation part that partially exposes the filter so that the vent hole is blocked by the filter.

16. The pellicle frame according to claim 15, wherein
the filter has a shape of a sheet that extends horizontally and is arranged with its surface standing upright,
the filter fixing device includes a pair of fixing members to which both sides of the filter contact respectively, and
each of the fixing members has the ventilation part formed in an inner area of its edge area.

17. The pellicle frame according to claim 16, wherein at least one of the fixing members has a receiving part for receiving the filter, the receiving part being formed to be recessed on the edge area of a surface that contacts the filter.

18. The pellicle frame according to claim 17, wherein a recess is formed in one of the fixing members and a protrusion is formed in the other fixing member, so that the pair of fixing members are mutually engaged by inserting the protrusion into the recess.

19. The pellicle frame according to claim 18, wherein the protrusion is inserted into the recess with a part of the filter inserted into the recess.

20. A pellicle assembly comprising:
a pellicle frame as described in claim 1; and
a pellicle attached to the pellicle frame.
